(19) United States
(12) Patent Application Publication
(10) Pub. No.: US 2024/0312979 A1
(43) Pub. Date: Sep. 19, 2024

(54) SEMICONDUCTOR DIODE STRUCTURE

(71) Applicant: Taiwan Semiconductor Manufacturing Company, Ltd., Hsinchu (TW)

(72) Inventors: Tao-Yi Hung, Hsinchu (TW); Wun-Jie Lin, Hsinchu (TW); Jam-Wem Lee, Hsinchu (TW); Kuo-Ji Chen, Taipei City (TW)

(21) Appl. No.: 18/365,483

(22) Filed: Aug. 4, 2023

Related U.S. Application Data
(60) Provisional application No. 63/490,964, filed on Mar. 17, 2023.

(51) Int. Cl. H01L 27/02; H01L 29/06; H01L 29/423; H01L 29/66; H01L 29/775; H01L 29/786

(52) U.S. Cl. CPC H01L 27/0255; H01L 29/0673; H01L 29/42392; H01L 29/66439; H01L 29/66545; H01L 29/775; H01L 29/78696

(57) ABSTRACT

A diode structure includes a silicon remaining layer, a first p-type doping region disposed on the silicon remaining layer and a first n-type doping region disposed on the silicon remaining layer. A first channel region is disposed on the silicon remaining layer and between the p-type doping region and the n-type doping region, wherein the first channel region, the first p-type doping region, and the first n-type doping region are disposed along a first direction.

### CROSS-REFERENCE TO RELATED APPLICATION

This application claims the benefit of commonly assigned U.S. Provisional Patent Application No. 63/490,964, filed on Mar. 17, 2023, which is incorporated by reference in its entirety.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon. The semiconductor industry continues to improve the integration density of various electronic components (e.g., transistors, diodes, resistors, capacitors, etc.) by continual reductions in minimum feature size, which allow more components to be integrated into a given area. Protection of semiconductor devices from electrostatic discharge (ESD) is important, since ESD can cause substantial damage to such devices. Often, semiconductor devices with smaller process geometries are more susceptible to degradation and damage due to ESD. To protect the devices against ESD degradation and damage, ESD protection devices are added to the semiconductor devices. Some ESC protection devices employ diodes since they are inexpensive and effective.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the invention and are not intended to be limiting.

FIG. 1 is a schematic diagram illustrating an example of an ESD protection circuit in accordance with disclosed embodiments.

FIG. 2 is a section view illustrating an example of a semiconductor device including a diode structure in accordance with disclosed embodiments.

FIG. 3 is a top view illustrating aspects of the semiconductor device shown in FIG. 2 in accordance with disclosed embodiments.

FIG. 4 is a section view illustrating another example of a semiconductor device including a diode structure in accordance with disclosed embodiments.

FIG. 5 is a top view illustrating aspects of the semiconductor device shown in FIG. 4 in accordance with disclosed embodiments.

FIG. 6 is a section view illustrating a further example of a semiconductor device including a diode structure in accordance with disclosed embodiments.

FIG. 7 is a top view illustrating aspects of the semiconductor device shown in FIG. 6 in accordance with disclosed embodiments.

FIG. 8 is a schematic diagram illustrating an example of a diode circuit in accordance with disclosed embodiments.

FIG. 9 is a section view illustrating example of a semiconductor device including a diode structure as shown in FIG. 8 in accordance with disclosed embodiments.

FIG. 10 is a schematic diagram illustrating another example of a diode circuit in accordance with disclosed embodiments.

FIG. 11 is a section view illustrating example of a semiconductor device including a diode structure as shown in FIG. 10 in accordance with disclosed embodiments.

FIG. 12 is a section view illustrating a further example of a semiconductor device including a diode structure in accordance with disclosed embodiments.

FIG. 13 is a top view illustrating aspects of the semiconductor device shown in FIG. 12 in accordance with disclosed embodiments.

FIG. 14 is a section view illustrating another example of a semiconductor device including a diode structure in accordance with disclosed embodiments.

FIG. 15 is a section view illustrating another example of a semiconductor device including a diode structure in accordance with disclosed embodiments.

FIG. 16 is a flow diagram illustrating an example of a method in accordance with disclosed embodiments.

FIGS. 17-26 are cross section views illustrating intermediate stages of forming an example of a semiconductor device including a diode structure in accordance with disclosed embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Protection of semiconductor devices from electrostatic discharge (ESD) is important, since ESD can cause substantial damage to such devices. Often, semiconductor devices with smaller process geometries are more susceptible to degradation and damage due to ESD. To protect the devices against ESD degradation and damage, ESD protection devices are added to the semiconductor devices. Some ESC protection devices employ diodes since they are inexpensive and effective.

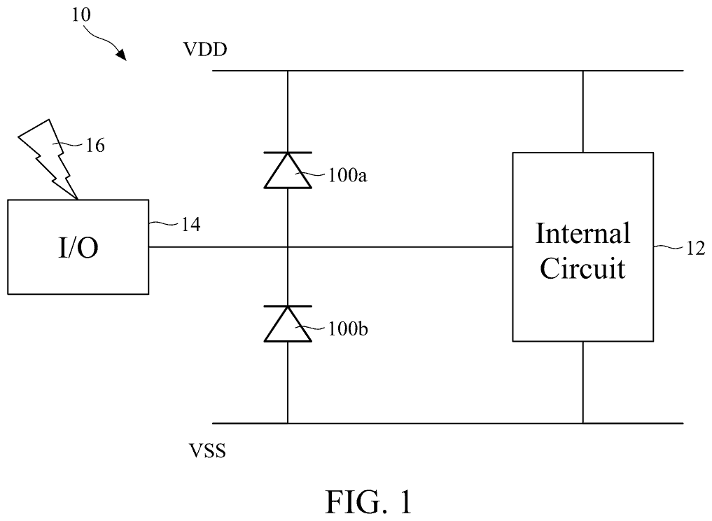

FIG. 1 illustrates an example of an ESD protection circuit 10 in accordance with aspects of the present disclosure. The ESD 10 protection circuit is arranged to protect an internal circuit 12 that includes electronic components from damage due to electrostatic discharge.

The ESD protection circuit 10 includes first and second diodes 100a, 100b (collectively “diodes 100”) connected between an input/output (IO) terminal 14 and respective voltage terminals VDD and VSS (e.g. ground). During normal non-ESD operation, the current from the IO terminal 14 is passed to the internal circuit 12. If an ESD event 16 occurs, the diodes 100 may be placed in a reverse bias condition, and transmit the ESD current safely to ground to avoid exposing the components of the internal circuit 12 to the high ESD voltage. Other ESD diode protection arrangements are within the scope of the disclosure.

Semiconductor devices are typically fabricated by sequentially depositing insulating or dielectric layers, conductive layers, and semiconductor layers of material over a semiconductor substrate, and patterning the various material layers using lithography to form circuit components and elements thereon. In some examples, the diodes 100 are body diodes formed in the semiconductor device. More particularly, the diodes 100 of the ESD protection circuit 10 may include body diodes formed by the p-type and n-type semiconductors of a semiconductor device, which may be created by doping an intrinsic silicon semiconductor with respective elements.

The semiconductor industry continues to improve the integration density of various electronic components (e.g., transistors, diodes, resistors, capacitors, etc.) by continual reductions in minimum feature size, which allow more components to be integrated into a given area. One such process for reducing semiconductor device size includes removing a bulk of the semiconductor substrate by thinning the semiconductor wafer (i.e. bulk-less processes). For example, certain dual-side power rail devices (sometimes referred to as a “super power rail” (SPR) technology or process) may employ bulk-less processes. With such dual-side power rail devices, each of the front side interconnect structure and the back-side interconnect structure of the semiconductor device may include a power delivery network (PDN) and IO pins. By including the PDN, the IO pin, and the power rail at the back-side interconnect structure, area and resistance benefits may be realized. Further, the PDN and IO pins at the front side interconnect structure allow for testing through the front side interconnect structure when the back side interconnect structure is removed.

As noted above, in some embodiments the diodes 100 of the ESD protection circuit 10 are body diodes formed by p-n junctions in the semiconductor device structure, where the diode's conducting path is formed in the device substrate. With devices employing bulk-less processes, the conducting path used by the diode is reduced, which could degrade diode performance for ESD protection. Removing portions of the substrate with the bulk-less process reduces the cross-sectional area of the diode, which increases the resistance of diode and thus also reduces the diode's capability to conduct current.

Disclosed embodiments provide a gated diode structure that is particularly useful with bulk-less structures for an ESD protection circuit such as the circuit 10. While some embodiments are disclosed in conjunction with ESD protection circuits such as the circuit 10 of FIG. 1, the disclosure is relevant for other diode applications, particularly those associated with bulk-less structures. In accordance with disclosed examples, a semiconductor device has a substrate (e.g. silicon) remaining layer, which may be a portion of a semiconductor substrate that is not removed in a bulk-less process. A p-type doping region is disposed on the silicon remaining layer, and an n-type doping region is disposed on the silicon remaining layer. A channel region is disposed on the silicon remaining layer between the p-type doping region and the n-type doping, and a gate structure wraps around the channel. Thus, a diode is formed at the junction of the p-type and n-type doping regions. The silicon remaining layer provides a deeper current path for the diode, while still allowing for sufficient substrate bulk removal to reduce the device size and allow for processes such as dual-side power rails.

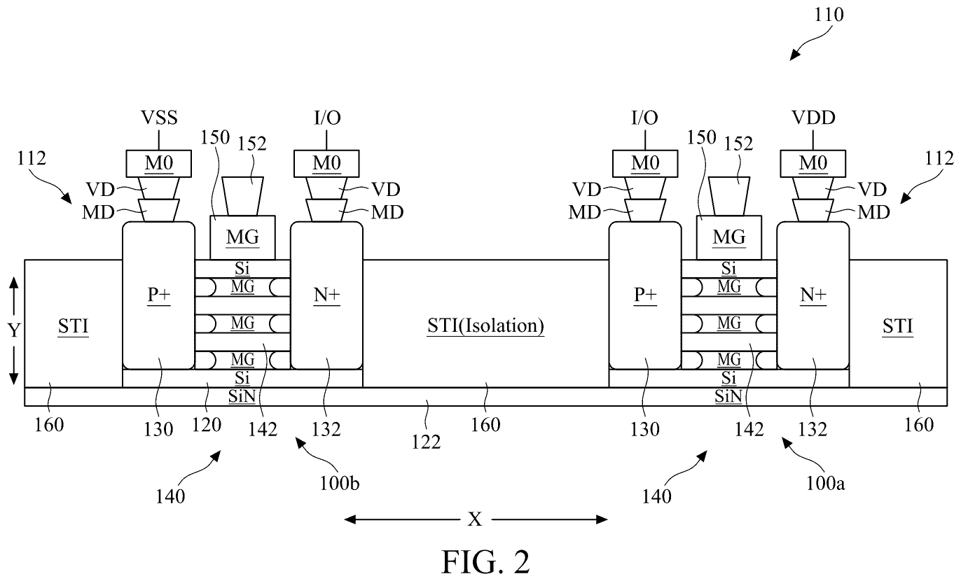

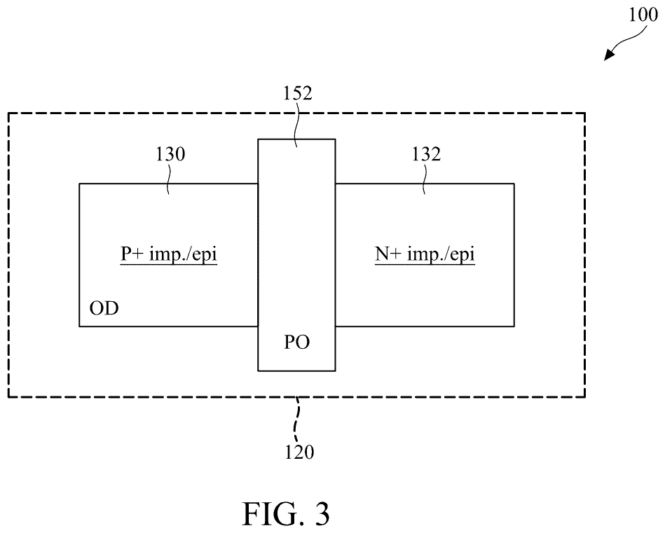

FIG. 2 is a section view, and FIG. 3 is a top view of an example of a semiconductor device 110 in accordance with the present disclosure. Some embodiments discussed herein are described in the context of a device including nano-FETs. However, the disclosure applies to other types of transistors (e.g., fin field effect transistors (FinFETs), planar transistors, or the like) in place of or in combination with the nano-FETs. Further, various disclosed embodiments refer to nano sheet gate-all-around (GAA) transistor structures, though disclosed aspects are applicable to other transistor and gate structures (e.g. FinFET, planar, etc.).

Two diodes 100, such as the diodes 110a and 110b shown in FIG. 1 are formed in the device 110. The semiconductor device 110 includes a silicon remaining layer 120. As noted above, in certain bulk-less processes, a bulk of the semiconductor substrate is removed by thinning the semiconductor wafer. In other words, a portion of the semiconductor substrate is removed in a vertical or Y direction. Among other things, this can facilitate processes for manufacturing semiconductor devices having dual-side power rail structures. With the example shown in FIGS. 2 and 3, a portion of the silicon substrate is not removed, resulting in the silicon remaining layer 120. In some implementations, about 10 nm-100 nm of the silicon substrate is reserved to form the silicon remaining layer 120. As such, the silicon remaining layer 120 is about 10 nm-100 nm thick in the Y direction in some examples. The silicon remaining layer 120 can be doped or undoped. For example, if the original silicon substrate is doped, the silicon remaining layer 120 is also doped, while if the original substrate is undoped, it may not be necessary to additionally dope the silicon remaining layer 120.

A p-type doping region 130 is disposed on or over a front side of the silicon remaining layer 120, and an n-type doping region 132 is also disposed on or over the front side of the silicon remaining layer 120. Nanostructures (e.g., nanosheets, nanowire, or the like) are disposed on or over the front side of the silicon remaining layer 120. The nanostructures act as channel regions 140 for the diodes 100 of the semiconductor device 110. The nanostructures may include p-type nanostructures, n-type nanostructures, or a combination thereof. In the example of FIG. 2, the nanostructures include a stack of silicon nanosheets 142 disposed on or over the silicon remaining layer 120 and between the p-type doping region 130 and the n-type doping region 132. Both the silicon remaining layer 120 and silicon channel region 140 (i.e. silicon nanosheets 142) function as the conducting path of the diode 100. As shown in FIGS. 2 and 3, the stack of silicon nanosheets 142 and the p-type and n-type doping regions 130, 132 are arranged or disposed laterally along a first or horizontal direction X.

A metal gate 150 wraps around the silicon nanosheets of the stack of silicon nanosheets 142 to form a GAA structure. Conductive contacts are formed by various conductive layers of the device 100. For instance, polysilicon gate lines 152 are formed over the metal gate 150 to provide conductive gate contacts for the nano-FETs 112. The metal gate 150 can be electrically floating or connected to a gate control. Thus, depending on whether a p-type or n-type channel exists, the gate control can provide a logic high (e.g., VDD/VSS) to “turn-on” the inversion layer and strengthen the carrier's mobility, and provide a logic low (e.g., VSS/VDD) to “turn-off” the channel layer to suppress leakage current.

Metal depositions MD are formed over the p-type and n-type doping regions 130, 132, which connect the p-type doping region 130 and the n-type doping region 132 to an MO metal layer by contact vias VD. The MO layer provides contact terminals for connecting the diode 100a between the IO 14 and the VDD rail, and for connecting the diode 100b between the IO 14 and the VSS rail as shown in FIG. 1.

Shallow trench isolation (STI) regions 160 are disposed between the p-type and n-type doping regions 130, 132. Although the STI regions 160 are illustrated as being separate from the silicon remaining layer 120, they may be integral with the silicon remaining layer 120. The example of FIG. 2 further includes a silicon nitride (SiN) barrier layer 122 below the silicon remaining layer 120.

Both the silicon remaining layer 120 and the silicon nanosheets 142 of the channel structure 140 function as the conducting path of diodes 100. As noted above, the silicon remaining layer 120 is reserved to provide a deeper current ESD conducting path for the diodes 100. While the deeper path formed by the silicon remaining layer 120 provides sufficient depth for conducting current resulting from an ESD event, it is not as deep a as conventional deep path (e.g. about 500 nm-600 nm), thus facilitating structures such as dual-side power rails.

The example shown in FIGS. 2 and 3 provides the diodes 100a and 100b, each having a single anode and cathode corresponding to the p-type and n-type doping regions 130 and 132. Other alternative embodiments provide diodes 100 having multiple anodes and cathodes. Such embodiments may have line widths (e.g., gate 152 length and pitch) that are smaller than that of the example shown in FIGS. 2 and 3. Further, embodiments having multiple anodes and cathodes may have a pattern density higher than that of the single anode/cathode example of FIGS. 2 and 3. However, the reduced line widths may more closely coordinate with line widths of standard GAA device processes. As such, processes for forming the diodes 100 are compatible with those for forming GAA devices, facilitating fabrication of both the diodes and the GAA devices in the same process.

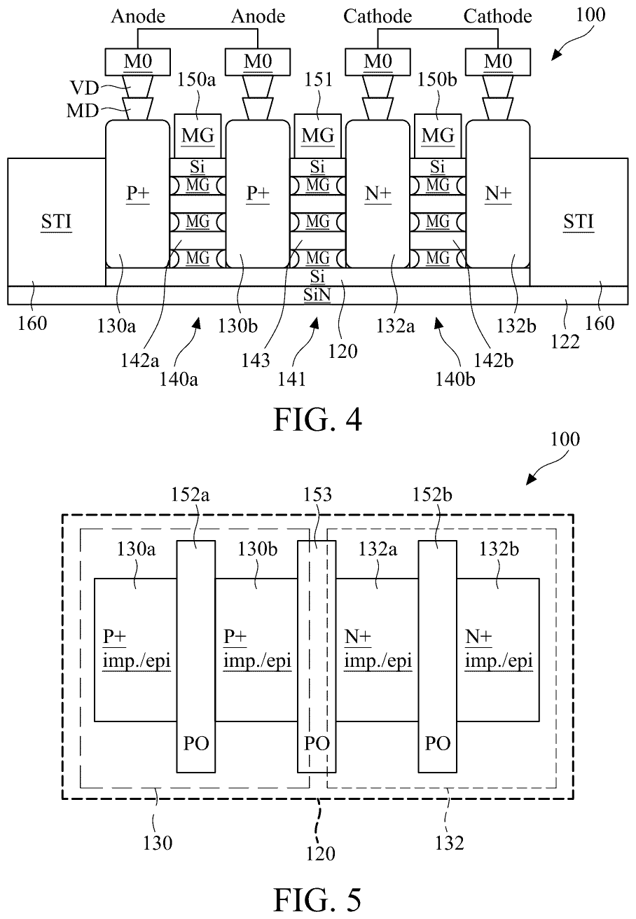

FIGS. 4 and 5 illustrate an example where the diode 100 includes two anodes and two cathodes. The two anode terminals are shorted together and the two cathode terminals are shorted together, effectively forming a single diode 100. As with the example of FIGS. 2 and 3, the diode 100 shown in FIGS. 4 and 5 includes the silicon remaining layer 120, which may be formed by a portion of the silicon substrate that is not removed during a bulk-less process. First and second p-type doping regions 130a. 130b are disposed on or over the silicon remaining layer 120, and first and second n-type doping regions 132a, 132b are disposed on or over the silicon remaining layer 120. Channel regions 140a. 140b include respective stacks of silicon nanosheets 142a, 142b. The stack of silicon nanosheets 142a is disposed on or over the silicon remaining layer 120 between the first and second p-type doping regions 130a, 130b. The stack of silicon nanosheets 142b is disposed on or over the silicon remaining layer 120 between the first and second n-type doping regions 132a, 132b. A further channel region includes another stack of silicon nanosheets 143 disposed between the second p-type doping regions 130b and the adjacent first n-type doping region 132a.

Metal gates 150a, 150b, 151 wrap around the silicon nanosheets of the respective stacks of silicon nanosheets 142a, 142b, 143. Polysilicon gate lines 152a, 152b, 153 (not shown in FIG. 4) are formed over the respective metal gates 150a, 150b, 151. The metal depositions MD are formed over the p-type and n-type doping regions 130, 132, and connect respective p-type doping regions 130a, 130b and n-type doping regions 132a, 132b to terminals formed in the MO metal layer by vias VD. The SiN barrier layer is situated below the silicon remaining layer 120. In the example of FIGS. 4 and 5, the two MO layer anode terminals are shorted together, while the two MO cathode terminals are shorted together.

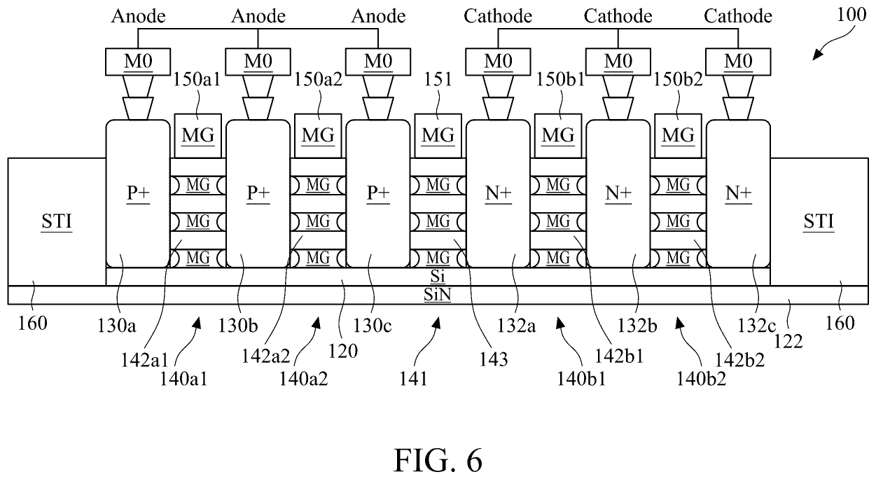

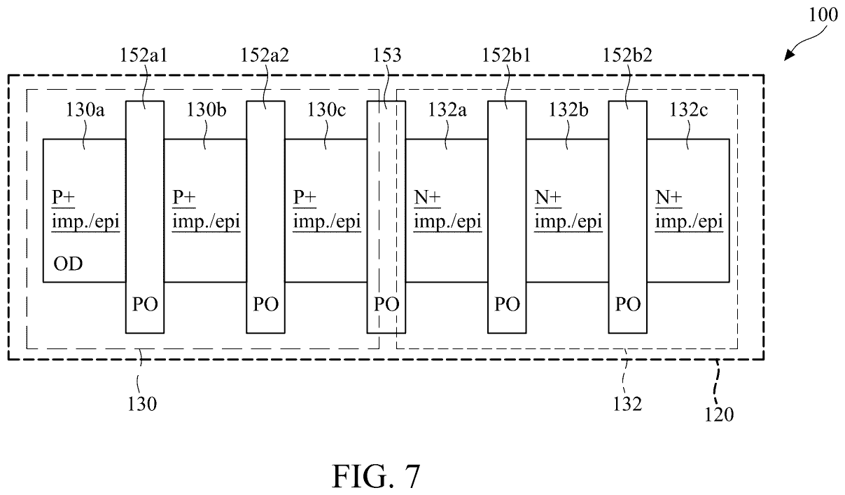

FIGS. 6 and 7 illustrate another example where the diodes 100 each have three MO cathode terminals shorted together and three MO anode terminals shorted together. Varying the number of anode and cathode terminals, for example, can allow further variation in line widths (e.g., gate 152 length and pitch) to allow further coordination with line widths of GAA device processes to improve compatibility such processes.

More particularly, the diode 100 shown in FIGS. 6 and 7 again includes the silicon remaining layer 120, which may be formed by a portion of the silicon substrate that is not removed during a bulk-less process. First, second and third p-type doping regions 130a, 130b, 130c are disposed on or over the silicon remaining layer 120, and first, second and third n-type doping regions 132a, 132b, 132c are disposed on or over the silicon remaining layer 120. Stacks of silicon nanosheets 142a1, 142a2 are respectively disposed on or over the silicon remaining layer 120 between the first and second p-type doping regions 130a, 130b and between the second and third p-type doping regions 130b, 130c. Stacks of silicon nanosheets 142b1, 142b2 are respectively disposed on or over the silicon remaining layer 120 between the first and second n-type doping regions 132a, 132b and between the second and third n-type doping regions 132b, 132c. The stack of silicon nanosheets 143 is disposed between the third p-type doping region 130c and the adjacent first n-type doping region 132a.

Metal gates 150a1, 150a2 wrap around the silicon nanosheets of the respective stacks of silicon nanosheets 142a1, 142a2. Metal gates 150b1, 150b2 wrap around the silicon nanosheets of the respective stacks of silicon nanosheets 142b1, 142b2. The metal gate 151 wraps around the silicon nanosheets of the stack of silicon nanosheets 143. Polysilicon gate lines 152a1, 152a2 are formed over the respective metal gates 150a1, 150a2. Polysilicon gate lines 152b1, 152b2 are formed over the respective metal gates 150b1, 150b2. The polysilicon gate line 153 is formed over the metal gate 151.

The metal depositions MD are formed over each of the p-type and n-type doping regions 130, 132, and connect respective p-type doping regions 130a, 130b, 130c and n-type doping regions 132a, 132b, 132c to terminals formed in the MO metal layer by the vias VD. The SiN barrier layer is situated below the silicon remaining layer 120. As noted above, in the example of FIGS. 6 and 7, the three MO layer anode terminals are shorted together, while the three MO cathode terminals are shorted together.

In the examples discussed in conjunction with FIGS. 4-7, the disclosed structure formed a single diode with multiple anode/cathode terminals shorted together. By changing terminal interconnections and dopant types and arrangements, the structure can be configured to form multiple diodes that may be connected in series or parallel as required.

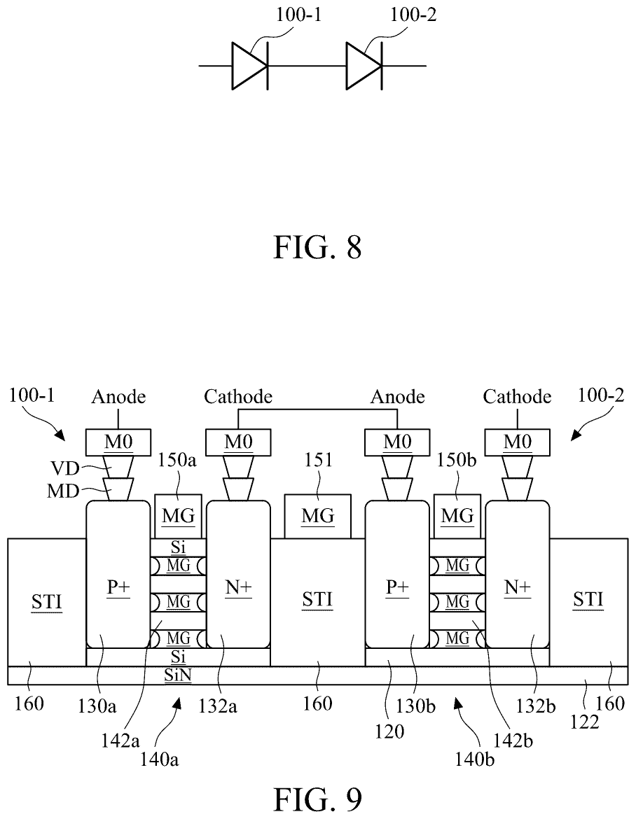

FIGS. 8 and 9 illustrate an example where two diodes 100 are formed and connected in series. The diodes include a first diode 100-1 and a second diode 100-2 connected in series as shown in FIG. 8. Referring now to FIG. 9, the first and second diodes 100-1, 100-2 each include the silicon remaining layer 120, which may be formed by a portion of the silicon substrate that is not removed during a bulk-less process. Each of the first and second diodes 100-1, 100-2 further include a respective p-type doping region 130a, 130b and a respective n-type doping region 132a, 132b disposed on or over the silicon remaining layer 120. Channel regions 140a, 140b with respective stacks of silicon nanosheets 142a, 142b are disposed on or over the silicon remaining layer 120 respectively between the p-type doping region 130a and n-type doping region 132a, and the p-type doping region 130b and n-type doping region 132b. An STI 161 is situated between the n-type doping region 132a of the first diode 100-1 and the p-type doping region 130b of the second diode 100-2. In the example of FIG. 9, the STI 161 is further situated between the silicon remaining layer 120, dividing the silicon remaining layer into two segments and thus removing a conduction path between the n-type doping region 132a of the first diode 100-1 and the p-type doping region 130b of the second diode 100-2. This further separates the diode structures of the first diode 100-1 and the second diode 100-2.

Metal gates 150a, 150b wrap around the silicon nanosheets of the respective stacks of silicon nanosheets 142a, 142b, and polysilicon gate lines (not shown in FIG. 9) 153 are formed over the respective metal gates 150a, 152b. In some examples, a further metal gate structure 151 is formed over the STI region 161 situated between the n-type doping region 132a of the first diode 100-1 and the p-type doping region 130b of the second diode 100-2. The metal depositions MD are formed over the p-type 130a, 130b and n-type doping regions 132a, 132b, and connect respective p-type doping regions 130 and n-type doping regions 132 to terminals formed in the MO metal layer by vias VD. The SiN barrier layer is situated below the silicon remaining layer 120. In the example of FIG. 9, cathode terminal (i.e. the n-type doping region 132a) of the first diode 100-1 is connected to the anode (i.e. the p-type doping region 130b) of the second diode 100-2. Conductive gate lines, such as the poly silicon gate lines may be formed over the metal gates 150a, 150b, 151 but are not shown in FIG. 9 for ease of illustration.

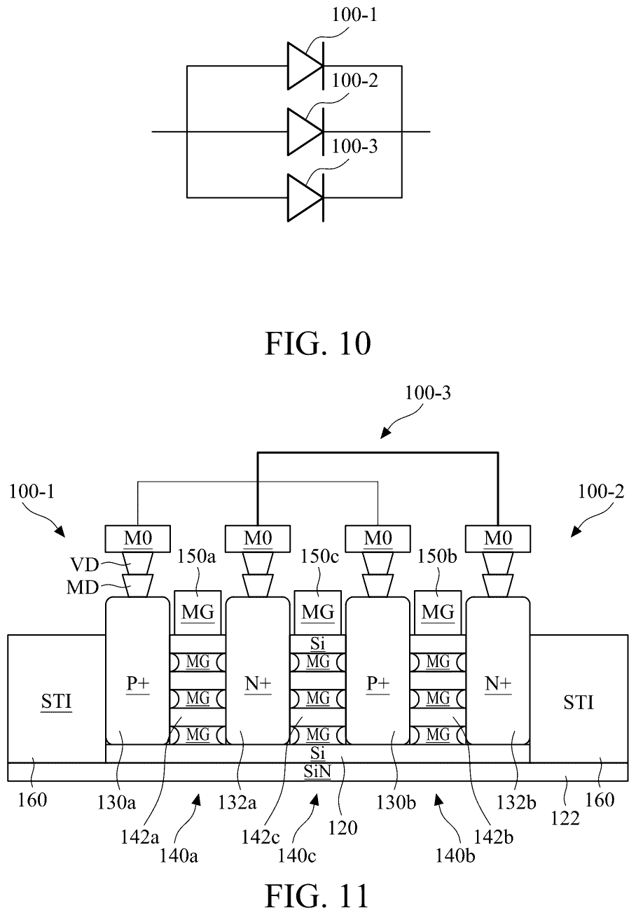

FIGS. 10 and 11 illustrate an example where three diodes 100 are formed and connected in parallel. The diodes include a first diode 100-1, a second diode 100-2 and a third diode 100-3 connected in parallel as shown in FIG. 10. The semiconductor structure shown in FIG. 11 is similar to that of FIG. 9, except rather than the STI 161 separating the first diode 100-1 and the second diode 100-2, a third channel region 140c is formed between the n-type doping region 132a of the first diode 100-1 and the p-type doping region 130b of the second diode 100-2, thus providing a third p-n junction between the n-type doping region 132a of the first diode 100-1 and the p-type doping region 130b of the second diode 100-2 to form the third diode 100-3.

In place of the STI 161, the example of FIG. 11 includes a third channel region 140c with a stack of silicon nanosheets 142c disposed on or over the silicon remaining layer 120 (the STI 161 is not in place to divide the silicon remaining layer laterally) between the n-type doping region 132a of the first diode 100-1 and the p-type doping region 130b of the second diode 100-2. As such, the third diode 100-3 is formed with the p-type doping region 130b forming its anode and the n-type doping region 132a forming its cathode. The cathode terminals (i.e. the n-type doping regions 132a, 132b) are connected together, and the anode terminals (i.e the p-type doping regions 130a, 130b) are connected together, thus connecting the first, second and third diodes 100-1, 100-2, 100-3 in parallel as shown in FIG. 10.

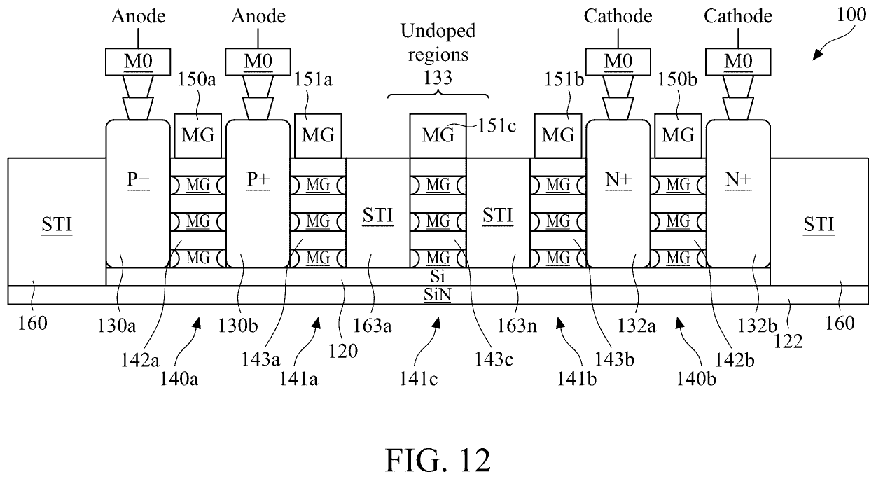

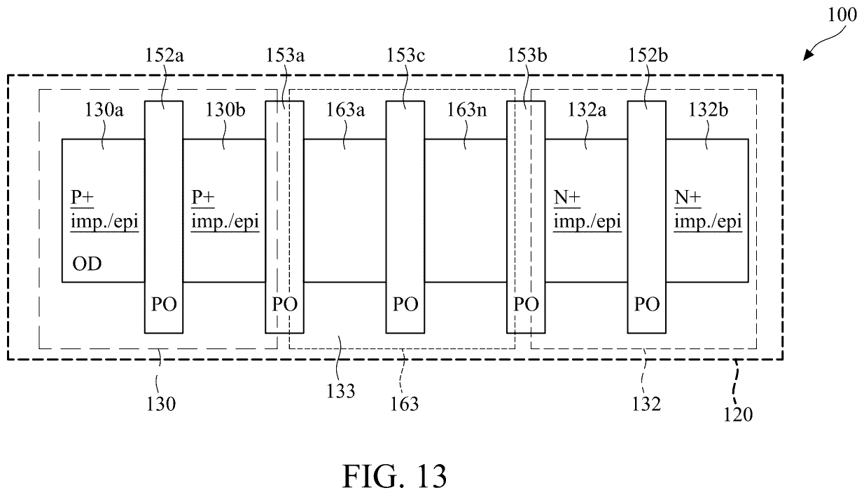

FIGS. 12 and 13 illustrate a further embodiment in which a plurality of undoped regions 133 are inserted between the p-type doping region 130 and the n-type doping region 132. With the undoped regions 133 laterally separating the p-type doping region 130 and the n-type doping region 132, the only current path for the diode 100 is in the silicon remaining layer 120. Providing the undoped regions 133 between the p-type doping region 130 and the n-type doping region 132 can improve the process window and enhance the breakdown voltage of the diode by increasing the distance between the p-type doping region and the n-type doping region.

FIG. 12 illustrates a side view of such a diode structure. The example of FIGS. 12 and 13 is similar to the embodiment discussed in conjunction with FIGS. 9 and 10, but in FIGS. 12 and 13 a plurality of undoped regions 133 including STI regions 163a-163n separate an adjacent p-type doping region 130 and n-type doping region 132. The example shown in FIGS. 12 and 13 includes the silicon remaining layer 120, which may be formed by a portion of the silicon substrate that is not removed during a bulk-less process. First and second p-type doping regions 130a, 130b are disposed on or over the silicon remaining layer 120, and first and second n-type doping regions 132a, 132b are disposed on or over the silicon remaining layer 120. Channel regions 140a, 140b include respective stacks of silicon nanosheets 142a, 142b. The stack of silicon nanosheets 142a is disposed on or over the silicon remaining layer 120 between the first and second p-type doping regions 130a, 130b. The stack of silicon nanosheets 142b is disposed on or over the silicon remaining layer 120 between the first and second n-type doping regions 132a, 132b.

As noted above, the second p-type doping region 130b is separated from the first n-type doping region 132a by a plurality of undoped regions 133. In some embodiments, the undoped regions 133 are STI regions 163a . . . 163n (collectively STI regions 163). The illustrated example shows two STI regions 163a and 163n, though additional STI regions 163 could be included in other embodiments. In the undoped regions 133, the STI structures 163 remain, and no epitaxial layers are grown in the undoped regions. As will be discussed further below, in some examples the semiconductor wafer is covered by an STI, which is then etched to form trenches for forming features such as the channel structures (e.g. nanosheets) and source/drain regions of FETs.

In the example shown and FIGS. 12 and 13, a channel region 141a including a stack of silicon nanosheets 143a is disposed between the second p-type doping region 130b and the first STI region 163a. Similarly, a channel region 141b including a stack of silicon nanosheets 143b is disposed between the first n-type doping region 132a and the Nth STI region 163n. Still further, a channel region 141c including a stack of silicon nanosheets 143c is disposed between the first STI region 163a and the Nth STI region 163n.

Metal gates 150a, 150b, 151a, 151b, 151c wrap around the silicon nanosheets of the respective stacks of silicon nanosheets 142a, 142b, 143a, 143b, 143c. Polysilicon gate lines 152a, 152b, 153a, 153b, 153c are formed over the respective metal gates 150a, 150b, 151a, 151b, 151c. The metal depositions MD are formed over the p-type and n-type doping regions 130, 132, and connect respective p-type doping regions 130a, 130b and n-type doping regions 132a, 132b to terminals formed in the MO metal layer by vias VD. The SiN barrier layer 122 is situated below the silicon remaining layer 120. In the example of FIGS. 12 and 13, the two MO layer anode terminals may be shorted together, and the two MO cathode terminals may be shorted together similarly to the embodiment shown in FIGS. 4 and 5. However, including a plurality of STI regions 163 between adjacent p-type and n-type doping regions 130, 132 is not limited to such an embodiment.

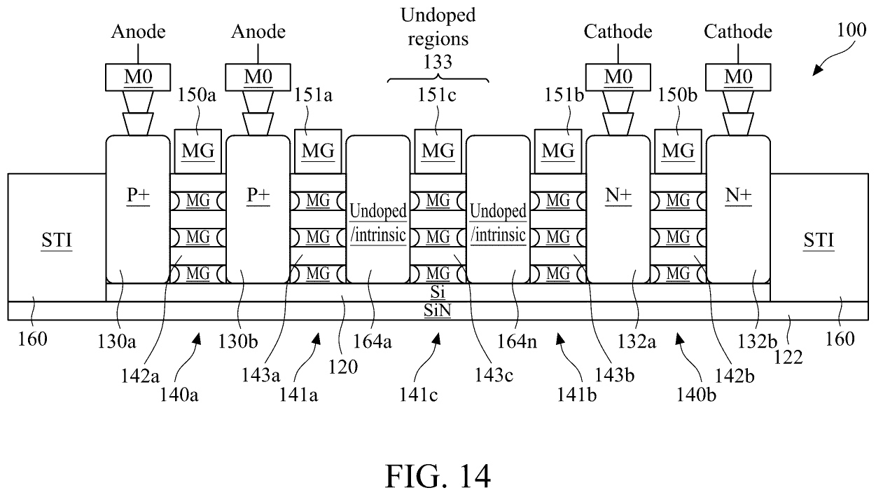

FIG. 14 illustrates a side view of another diode structure that is similar to the example shown in FIGS. 12 and 13. The example of FIG. 14 also includes a plurality of un-doped regions 133, but in FIG. 14 the undoped regions 133 include a plurality of undoped epitaxial layers 164 in place of the STI regions 163.

As with the previous examples, the example shown in FIG. 14 includes the silicon remaining layer 120, first and second p-type doping regions 130a, 130b disposed on or over the silicon remaining layer 120, and first and second n-type doping regions 132a, 132b disposed on or over the silicon remaining layer 120. The example of FIG. 14 further includes the channel regions 140a, 140b with stacks of silicon nanosheets 142a, 142b.

In FIG. 14, the second p-type doping region 130b is separated from the first n-type doping region 132a by a plurality of undoped regions 133 that include undoped epitaxial layers 164a . . . 164n. The illustrated example shows two undoped epitaxial regions 164a and 164n, though additional undoped epitaxial regions 164 could be included in other embodiments. In the undoped regions 133 shown in FIG. 14, epitaxial layers are grown in the undoped regions 133, but there is no implantation (i.e. doping) following the epitaxial growth. As with the examples shown in FIGS. 4 and 13, the MO layer anode terminals may be shorted together, and the two MO cathode terminals may be shorted together. However, including a plurality of undoped epitaxial regions 164 between adjacent p-type and n-type doping regions 130, 132 is not limited to such embodiments.

Thus, the diode 100 shown in FIG. 14 is similar to a PIN diode structure in which an undoped intrinsic semiconductor region is placed between a p-type semiconductor region and an n-type semiconductor region. The breakdown voltage in the diode 100 shown in FIG. 14 will be lower than that of the example shown in FIGS. 12 and 13 due to the STI structures 163 being replaced by the undoped epitaxial regions 164. Moreover, the diode 100 shown in FIG. 14 has a conducting path in the undoped epitaxial layers 164 in addition to the silicon remaining layer 120.

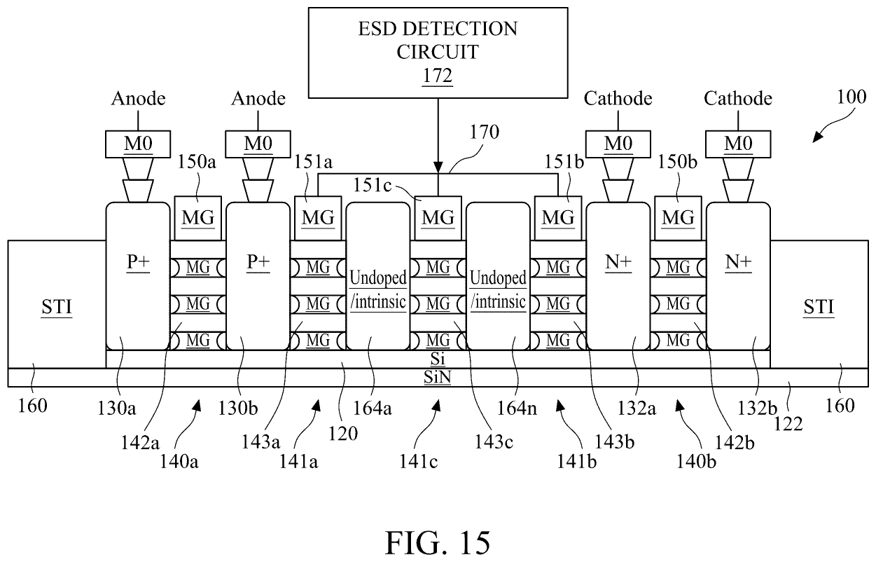

FIG. 15 is a side view showing the diodes structure of FIG. 14, further including a gate control input terminal 170 connected to the metal gates 151a, 151b, 151c of the channel regions 141a, 141b, 141c situated between the second p-type doping region 130b and the first n-type doping region 132a. A similar gate control input terminal 170 could be provided for any of the previously disclosed embodiments that have a channel region situated between the p-type doping region 130 and the n-type doping region 132. The gate control input terminal 170 is configured to receive a gate control signal to selectively open or close the current path between the diodes p-n junction.

The gate control signal may be applied to the gate control input terminal 170, for example, by an ESD detection circuit 172. In some examples, such an ESD detection circuit 172 is configured such that, in a standby mode where there is no ESD source and the internal circuit 12 (see FIG. 1) is in stable operation, a control signal is output to the gate control input terminal 170 to further “turn-off” the diode 100, thereby suppressing leakage current. For diodes having underlying p-type channel layers, a logic low signal would be output to the gate control input terminal 170 in the standby mode, while a logic high signal would be output for n-type channel layers.

When an ESD event is detected, the ESD detection circuit 172 outputs a control signal to the gate control input terminal 170 to “turn-on” the diode's inversion layer and strengthen carrier mobility. For a diode having p-type channel layers, a logic high control signal would be output, while a logic low signal would be output for n-type channel layers.

Further embodiments may connect additional metal gates to receive a gate control signal. For example, the metal gate 150a between the first and second p-type doping regions 130a. 130b can receive a logic high control signal to further “turn-off” the diode, and receive a logic low control signal to “turn-on” the diode, while the metal gate 150b between the first and second n-type doping regions can receive a logic low control signal to “turn-off” and receive a logic high control signal to “turn-on.” Similar control signals could be applied to other disclosed embodiments. In other examples, a gate control signal is not provided and the metal gate(s) 151 between the p-type doping region 130 and the n-type doping region 132 (and other metal gates) are left to float.

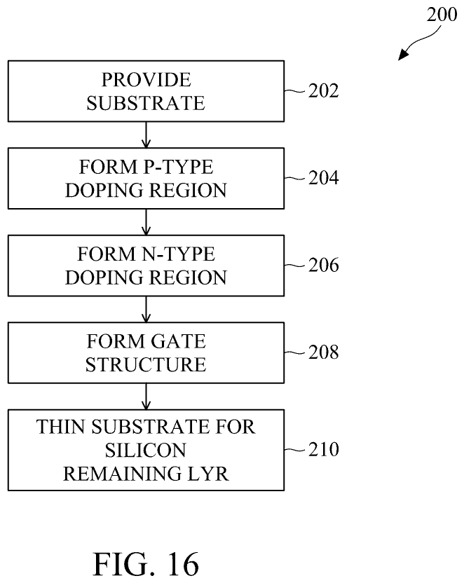

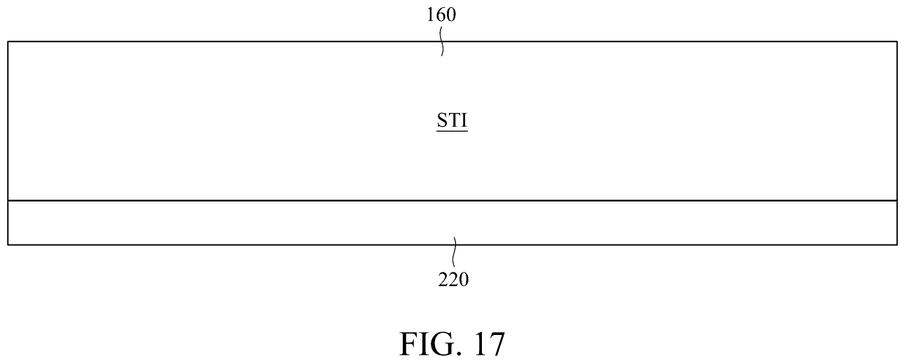

FIG. 16 is a flow diagram illustrating an example of a method 200 for forming a diode, and FIGS. 17-25 illustrate various aspects of an example process flow for forming the diodes 100 disclosed herein. As noted above, the disclose process may be carried out together with a typical GAA device fabrication process. Referring to FIG. 16 together with FIG. 17, a substrate 220 with an STI 160 is provided at operation 202. The substrate 220 may be a semiconductor substrate, such as a bulk semiconductor, a semiconductor-on-insulator (SOT) substrate, or the like, which may be doped (e.g., with a p-type or an n-type dopant) or undoped. The substrate 220 may be a wafer, such as a silicon wafer. Other substrates, such as a multi-layered or gradient substrate may also be used. In some embodiments, the semiconductor material of the substrate 220 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The STI 160 may be formed by depositing an insulation material over the substrate 220. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. The insulation material is then recessed to form the STI 160.

Operation 204 of FIG. 16 includes forming the p-type doping regions 130 on the substrate 220, and operation 206 includes forming n-type doping regions 132 on the substrate 220. Operation 208 includes forming the channel region 140 on the substrate 220 between the p-type doping region 130 and the n-type doping region 132.

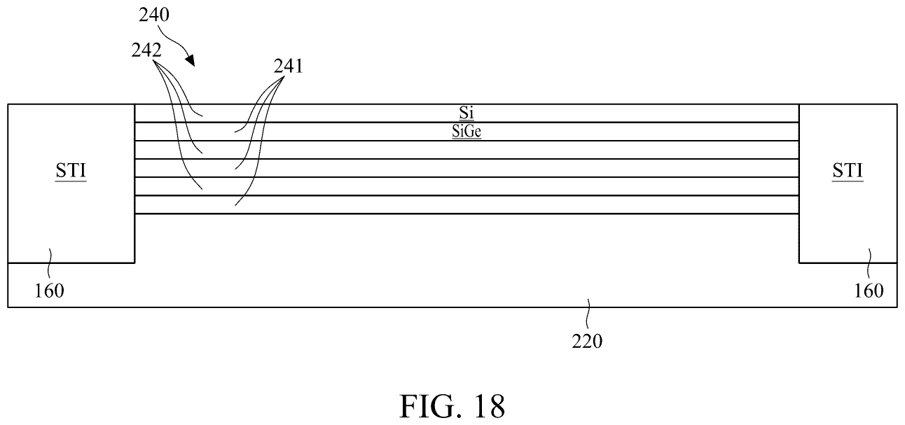

In FIG. 18, formation of the p-type doping regions 130, the n-type doping regions 132, and channel region 140 includes an etching process and nanosheet formation. For example, the STI 160 may be etched for form one or more trenches, and a stack of alternating layers 240 is formed on the substrate 220. The stack of alternating layers 240 includes alternating layers of first semiconductor layers 241 of a first semiconductor material (e.g., SiGe layers) and second semiconductor layers 242 of a second semiconductor material (e.g., Si layers). Each of the first semiconductor layers 241 (e.g., SiGe layers) and the second semiconductor layers 242 (e.g., Si layers), in some embodiments, is epitaxially grown on its underlying layer. The stack of alternating layers 240 can include any number of the first semiconductor layers 241 a (e.g., SiGe layers) and any number of the second semiconductor layers 242 (e.g., Si layers). The epitaxial growth can use CVD, MOCVD, MBE, LPE, VPE, UHVCVD, or the like, or a combination thereof. Each of the first semiconductor layers 241 and the second semiconductor layers 242 (e.g., Si layers) can be a group IV material, such as Si, Ge, SiGe, SiGeSn, SiC or the like; a group III-group V compound material, such as GaAs, GaP, GaAsP, AlInAs, AlGaAs, GaInAs, InAs, GaInP, InP, InSb, GaInAsP or the like.

The stacks of alternating layers 240 can include any number of the first semiconductor layers 241 and any number of the second semiconductor layers. As illustrated, for example, the stack of alternating layers 240 has three first semiconductor layers 241 and three second semiconductor layers. The numbers of the first semiconductor layers 241 and the second semiconductor layers 242 may be modulated by the number of cycles of epitaxial growth used to form the first stack of alternating layers, respectively.

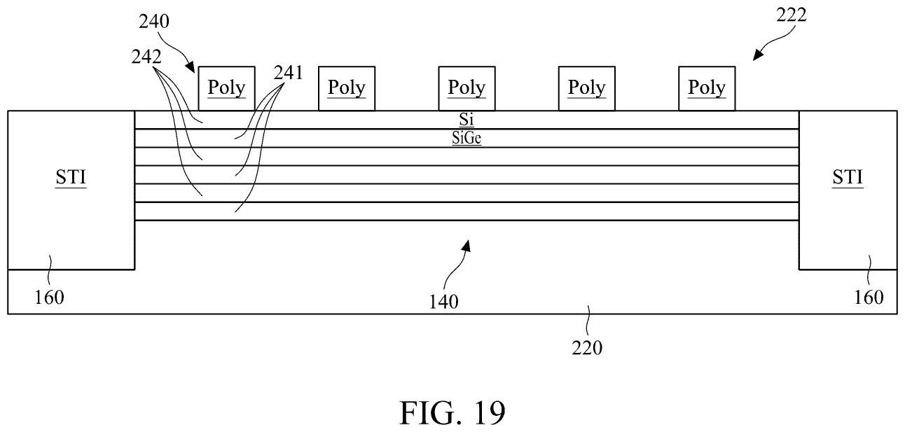

In FIG. 19, dummy gates 222 are formed over the STI 160 and a channel region 140 is formed. The channel region 140 may include any suitable channel structure, such as nanosheet, finfet, planar, etc. A dummy gate layer may be deposited over the STI 160 and then planarized, such as by a CMP. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. In the illustrated example, the dummy gate layer includes dummy gates 222 formed from polysilicon, and the channel region 140 includes nanostructures (e.g., nanosheets) over fins on the substrate 220, where the nanosheets act as the channel regions.

A mask layer may be patterned using suitable photolithography and etching techniques to form masks, and the pattern of the masks then may be transferred to the dummy gate layer form the dummy gates 222. The dummy gates 222 cover respective channel regions 140 of the fins. The pattern of the masks may be used to physically separate each of the dummy gates 222 from adjacent dummy gates 222.

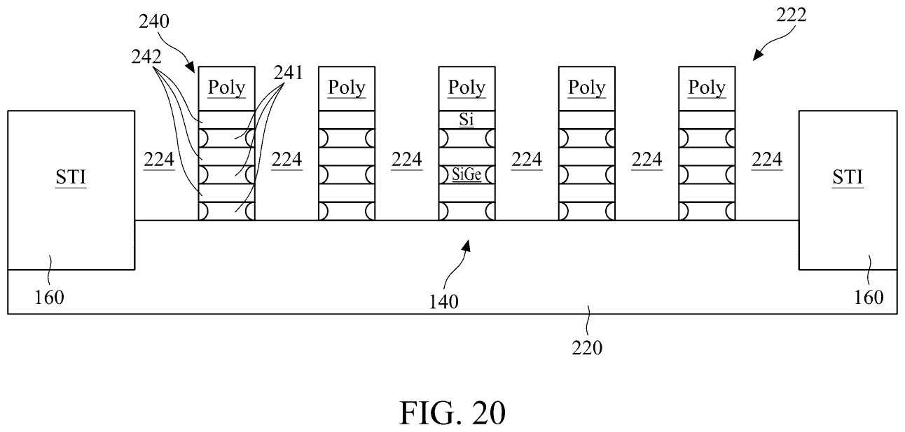

FIG. 20 illustrates formation of trenches 224 etched in the stack of alternating layers 240 to form the channel regions 140. The etching may be any acceptable etch process, such as a reactive ion etch (RE), neutral beam etch (NBE), the like, or a combination thereof. The etching may be anisotropic.

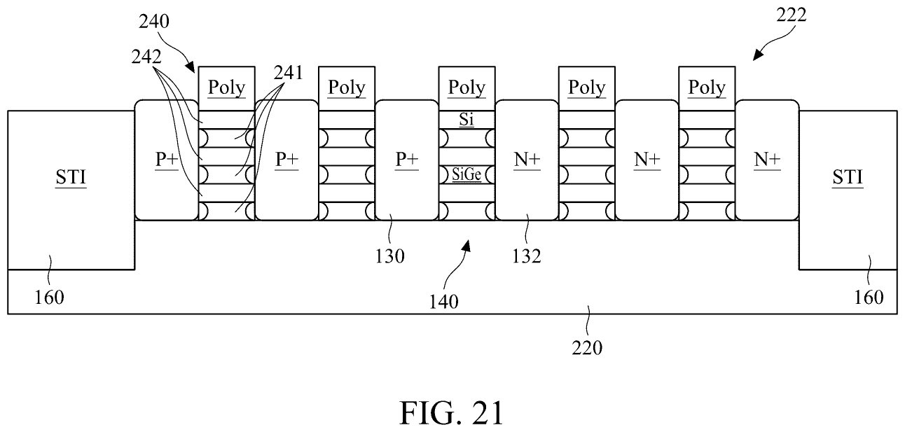

In FIG. 21, the p-type doping regions 130 and n-type doping regions 132 are formed on opposing sides of the dummy gate stacks in accordance with operations 204 and 260 of FIG. 16. Some examples use epitaxially grown materials, which may be varied for the p-type doping regions 130 and n-type doping regions 132. The epitaxial n-type doping regions 130 and p-type doping regions 132 may be doped either through an implanting process to implant appropriate dopants, or by in-situ doping as the material is grown. In some embodiments, the epitaxial n-type doping regions 130 are formed of SiC or SiP doped with phosphorus (P) to form an n-type regions and the epitaxial p-type doping regions 132 are formed of SiGe or Ge doped with boron (B) to form a p-type regions.

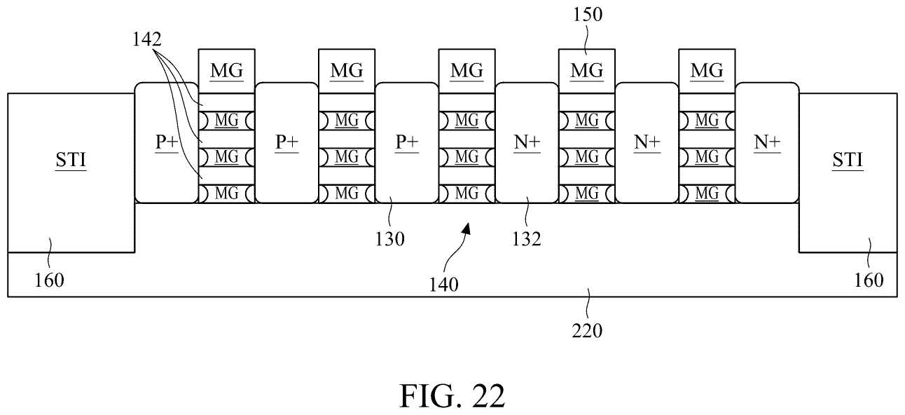

A gate replacement process is performed in FIG. 22 for forming the metal gates 150. In FIG. 22, the dummy gates 222 and stack of alternating layers 240 are processed to remove the dummy gates 222 and the first semiconductor layers 241. A selective removal process for the first semiconductor layers 241 (e.g., SiGe layers) is performed in the channel regions 140. In embodiments in which the first semiconductor layers 241 are SiGe and the second semiconductor layers 242 are formed of Si, the first semiconductor layers 241 may be removed, for example, by an NMOS SiGe selective removal process. In some embodiments, the selective removal process may use an etchant that selectively etches the silicon germanium at a higher rate than the silicon, such as NH4OH:H2O2:H2O (ammonia peroxide mixture, APM), H2SO4+H2O2 (sulfuric acid peroxide mixture, SPM), or the like. Other suitable processes and materials may be used. This selective etching process removes the first semiconductor layers 241, leaving the stack of silicon nanosheets 140.

Further, in FIG. 22, the metal gates 150 are formed over the exposed portions of the stack of nanosheets 140 in the space vacated by the removal of the dummy gates 222 and first semiconductor layers 241. Gate dielectrics may be formed, which may comprise SiO2, SiON, Si3N4, HfOx, LaOx, and/or AlOx. A metal gate structure is formed on the gate dielectrics to form the metal gates 150. The metal gate structure can be a multi-layered structure. As illustrated in FIG. 22, the metal gate structure 150 fills the space remaining between the nanosheets of the stack of nanosheets 142, and may be within cavities enclosed by gate dielectrics. In some examples, a planarization process, such as a CMP, may be performed to remove the excess portions of the metal gate structure and the gate dielectric.

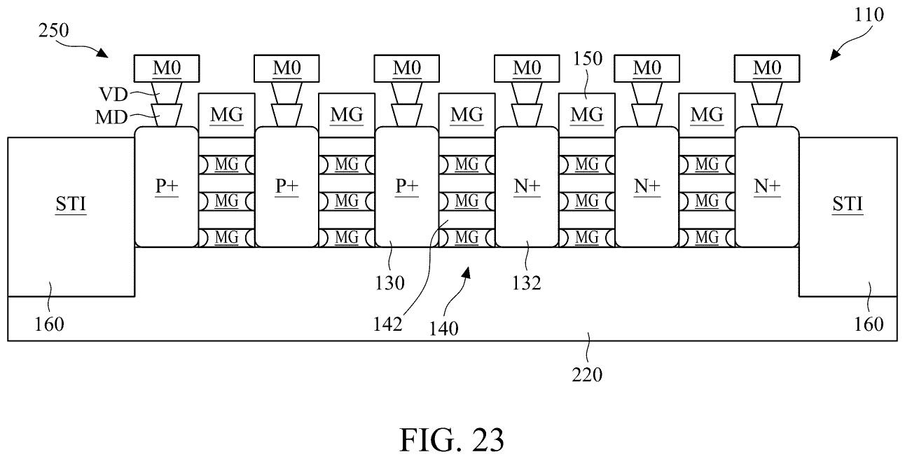

In FIG. 23, a front side interconnect structure 250 is formed on a front side of the device, for example, over the p-type doping regions 130 and n-type doping regions 132. The front side interconnect structure 250 may comprise conductive lines and conductive vias interconnecting the layers of conductive lines, including the metal depositions MD, conductive vias VD, MO connections, etc., which may be formed one or more stacked dielectric layers. The conductive vias VD may extend through respective ones of the dielectric layers to provide vertical connections between layers of the conductive lines such as the MD and MO layers. The front side interconnect structure 250 may be formed through any acceptable process, such as a damascene process, a dual damascene process, or the like. The front side interconnect structure 250 may further include a front side power distribution network (PDN) front side I/O pins and front side power rails (e.g. VDD and VSS).

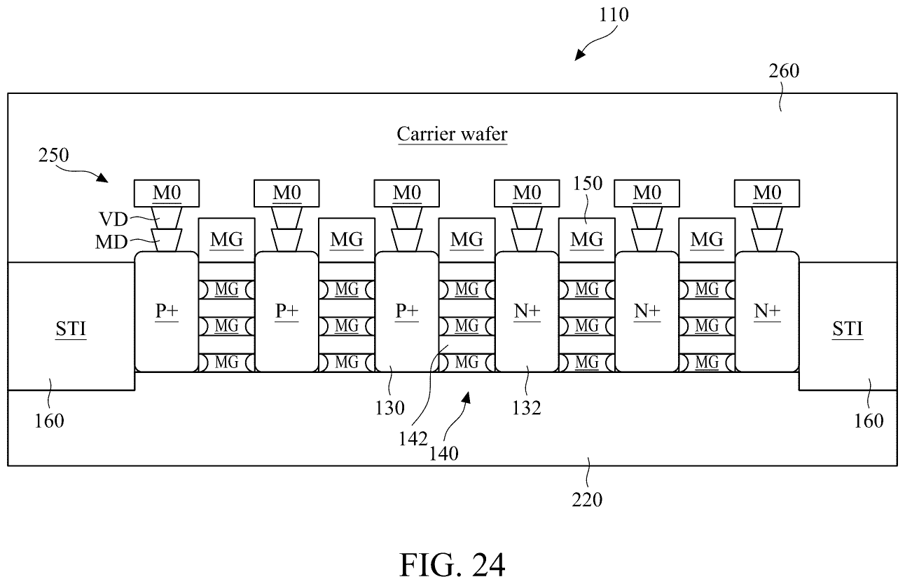

Operation 210 of FIG. 16 includes thinning the wafer 220 to form the silicon remaining layer 120. A carrier wafer 260 is bonded to a top surface of the front side interconnect structure 250 in FIG. 24. The carrier wafer may be bonded to the top surface by one or more bonding layers. The carrier wafer 260 may be a glass carrier substrate, a ceramic carrier substrate, a wafer (e.g., a silicon wafer), or the like. The carrier substrate 260 may provide structural support during subsequent processing steps and in the completed device. In various embodiments, the carrier 260 may be bonded to the front side interconnect structure 250 using a suitable technique, such as dielectric-to-dielectric bonding, or the like.

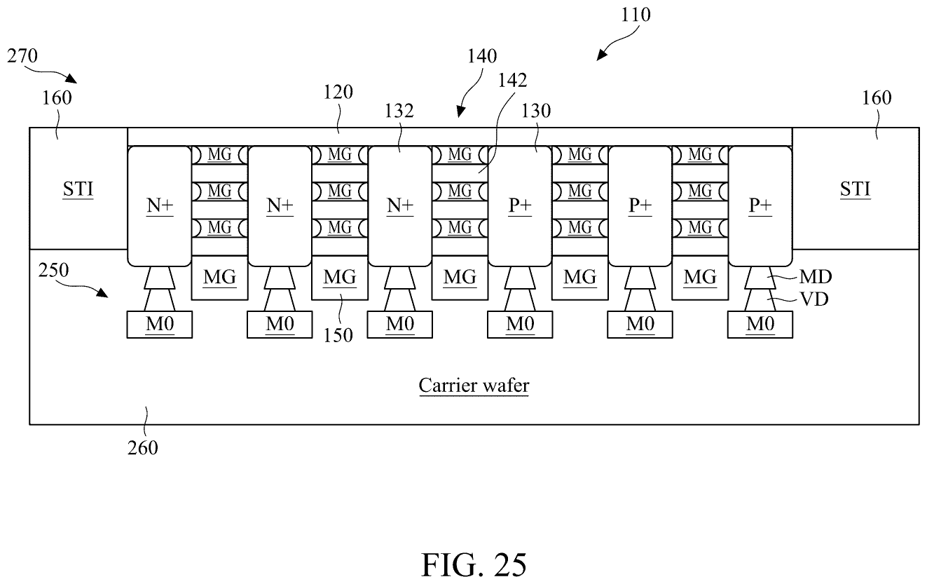

After the carrier wafer 260 is bonded to the front side interconnect structure 250, the device may be flipped such that a back side 270 of the device 110 faces upwards as shown in FIG. 25. The back side 270 (i.e. side adjacent the bottom of the p-type doping regions 132 and n-type doping regions 132 as shown in FIG. 25) may refer to a side opposite to the front side of the device 110 on which the front side interconnect structure 250 is formed.

After the device 110 is flipped as shown in FIG. 25 such that the back side 270 is facing upwardly, a thinning process may be applied to the back side 270 of the substrate 220. The thinning process may comprise a planarization process (e.g., a mechanical grinding, a CMP, or the like), an etch-back process, a combination thereof, or the like. With conventional thinning processes, the thinning process may expose bottom surfaces of the p-type doping regions 130 and n-type doping regions 132. In accordance with aspects of the present disclosure, a portion of the substrate 220 is not removed with the thinning process as shown in FIG. 25, resulting in the silicon remaining layer 120. In some examples, the thinning process is conducted such about 10 nm-100 nm of the substrate 220 remains, forming the silicon remaining layer 120.

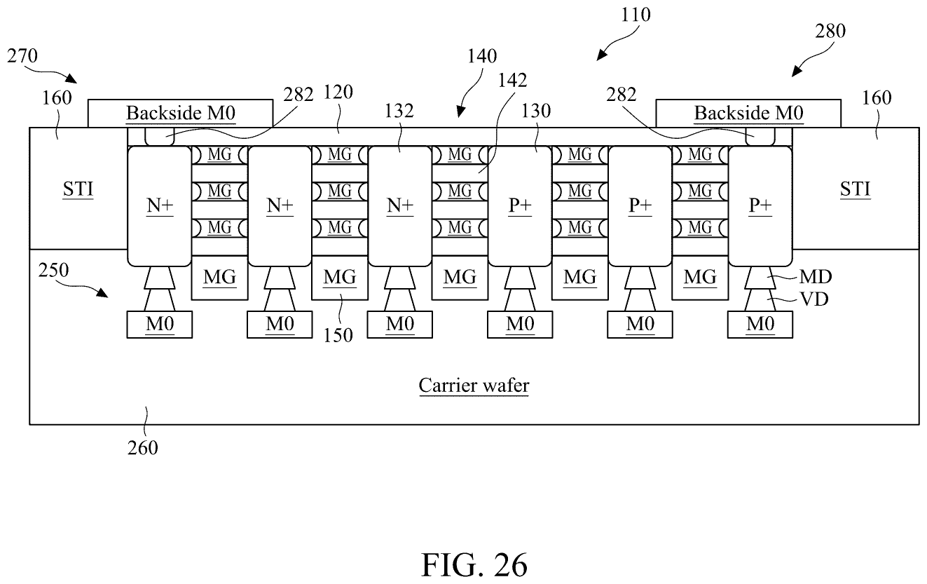

In FIG. 26, a back side interconnect structure 280 is formed, which may include suitable conductive vias, layers of conductive lines, layers of dielectric layers, etc. In some examples, the back side interconnect structure 280 includes the silicon nitride (SiN) barrier layer 122 shown in FIG. 2 below the silicon remaining layer 120. In the example of FIG. 26, a back side via 282 is shown extending through the silicon remaining layer 120 connecting to a back side MO layer. Moreover, the back side interconnect structure 280 may provide electrical connections to a back side PDN, I/O circuits, combinations thereof, or the like. After thinning the substrate 220, the carrier wafer 260 may be separated from the device 110.

Thus, thinning the substrate 220 so as to form the silicon remaining layer 120 allows standard GAA processing of the device and facilitates provision of the back side interconnect structure 280, which may include the back side PDN. Both the silicon remaining layer 120 and the silicon nanosheets 142 of the channel structure 140 function as the conducting path of diodes 100. As such, the silicon remaining layer 120 provides a deeper current ESD conducting path for the diodes 100. While the deeper path formed by the silicon remaining layer 120 provides sufficient depth for conducting current resulting from an ESD event, it is not as deep a as conventional deep path (e.g. about 500 nm-600 nm), thus facilitating structures such as dual-side power rails.

In accordance with aspects of the disclosure, a semiconductor diode structure is disclosed that includes a silicon remaining layer, a first p-type doping region disposed on the silicon remaining layer and a first n-type doping region disposed on the silicon remaining layer. A first channel region is disposed on the silicon remaining layer and between the p-type doping region and the n-type doping region, wherein the first channel region, the first p-type doping region, and the first n-type doping region are disposed along a first direction. The silicon remaining layer has a thickness of 10 nm-100 nm in a second direction that crosses the first direction

In accordance with further aspects, an ESD protection circuit includes a first voltage terminal and a a second voltage terminal. A first diode is configured to connect between the second voltage terminal and an input/output (IO) terminal. The first diode has a silicon remaining layer and a first p-type doping region disposed on a front side of the silicon remaining layer. The first p-type doping region forms a first anode of the first diode and is configured to connect to the IO terminal. A first n-type doping region is disposed on the front side of the silicon remaining layer. The first n-type doping region forms a first cathode of the first diode and is configured to connect to the second voltage terminal. A first channel region is disposed on the front side of the silicon remaining layer between the first p-type doping region and the first n-type doping region. A back side interconnect structure is disposed on a back side of the silicon remaining layer opposite the front side.

In accordance with additional aspects of the disclosure, a method for forming a diode structure includes providing a substrate, and forming a first p-type doping region and a first n-type doping region on the substrate. A first channel region is formed on the substrate between the p-type doping region and the n-type doping region. A portion of the substrate is thinned to leave a silicon remaining layer below the first p-type doping region, the first n-type doping region and the first channel region.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor diode structure, comprising:
a silicon remaining layer;
a first p-type doping region disposed on the silicon remaining layer;
a first n-type doping region disposed on the silicon remaining layer; and
a first channel region disposed on the silicon remaining layer and between the first p-type doping region and the first n-type doping region, wherein the first channel region, the first p-type doping region, and the first n-type doping region are disposed along a first direction;
wherein the silicon remaining layer has a thickness of 10 nm-100 nm in a second direction that crosses the first direction.

2. The semiconductor diode structure of claim 1, wherein the first channel region includes:
a first stack of silicon nanosheets disposed on the silicon remaining layer and between the first p-type doping region and the first n-type doping region, wherein the first stack of silicon nanosheets, the first p-type doping region, and the first n-type doping region are disposed along the first direction; and
a first metal gate wrapping around each of the silicon nanosheets of the first stack of silicon nanosheets.

3. The semiconductor diode structure of claim 2, further comprising:
a second p-type doping region disposed on the silicon remaining layer;
a second n-type doping region disposed on the silicon remaining layer;
a second stack of silicon nanosheets disposed on the silicon remaining layer and between the first p-type doping region and the second p-type doping region;
a second metal gate wrapping around each of the silicon nanosheets of the second stack of silicon nanosheets;
a third stack of silicon nanosheets disposed on the silicon remaining layer and between the first n-type doping region and the second n-type doping region; and
a third metal gate wrapping around each of the silicon nanosheets of the third stack of silicon nanosheets.

4. The semiconductor diode structure of claim 3, further comprising:
a first anode terminal connected to the first p-type doping region;
a second anode terminal connected to the second p-type doping region, wherein the first and second anode terminals are electrically connected;
a first cathode terminal connected to the first n-type doping region; and
a second cathode terminal connected to the second n-type doping region, wherein the first and second cathode terminals are electrically connected.

5. The semiconductor diode structure of claim 3, further comprising:
a first undoped region disposed on the silicon remaining layer, wherein the first stack of silicon nanosheets is disposed between the first undoped region and the first p-type doping region;
a second undoped region disposed on the silicon remaining layer;
a fourth stack of silicon nanosheets disposed on the silicon remaining layer and between the first undoped region and the second undoped region;
a fourth metal gate wrapping around each of the silicon nanosheets of the fourth stack of silicon nanosheets;
a fifth stack of silicon nanosheets disposed on the silicon remaining layer and between the second undoped region and the first n-type doping region; and
a fifth metal gate wrapping around each of the silicon nanosheets of the fifth stack of silicon nanosheets.

6. The semiconductor diode structure of claim 5, wherein the first undoped region and the second undoped region are shallow trench isolation structures.

7. The semiconductor diode structure of claim 5, wherein the first metal gate, the fourth metal gate and the fifth metal gate are electrically connected.

8. The semiconductor diode structure of claim 2, further comprising:
a second p-type doping region disposed on the silicon remaining layer;
a second n-type doping region disposed on the silicon remaining layer;
a second stack of silicon nanosheets disposed on the silicon remaining layer and between the second n-type doping region and the second p-type doping region; and
a second metal gate wrapping around each of the silicon nanosheets of the second stack of silicon nanosheets.

9. The semiconductor diode structure of claim 8, further comprising:
a third stack of silicon nanosheets disposed on the silicon remaining layer and between the first n-type doping region and the second n-type doping region; and
a third metal gate wrapping around each of the silicon nanosheets of the third stack of silicon nanosheets.

10. The semiconductor diode structure of claim 1, wherein the first p-type doping region, the first n-type doping region and the first channel region are disposed on a front side of the silicon remaining layer, and a back side interconnect structure disposed on a back side of the silicon remaining layer opposite the front side.

11. An ESD protection circuit, comprising:
a first voltage terminal;
a second voltage terminal;
a first diode configured to connect between the second voltage terminal and an input/output (IO) terminal, the first diode comprising:
a silicon remaining layer;
a first p-type doping region disposed on a front side of the silicon remaining layer, wherein the first p-type doping region forms a first anode of the first diode and is configured to connect to the IO terminal;
a first n-type doping region disposed on the front side of the silicon remaining layer, wherein the first n-type doping region forms a first cathode of the first diode and is configured to connect to the second voltage terminal; and
a first channel region disposed on the front side of the silicon remaining layer and between the first p-type doping region and the first n-type doping region; and
a back side interconnect structure disposed on a back side of the silicon remaining layer opposite the front side.

12. The ESD protection circuit of claim 11, wherein the first channel region includes a metal gate configured to receive a gate control signal.

13. The ESD protection circuit of claim 11, further comprising a second diode configured to connect between the first voltage terminal and the IO terminal, the second diode comprising:
the silicon remaining layer;
a second p-type doping region disposed on the silicon remaining layer, wherein the second p-type doping region forms a first anode of the second diode and is configured to connect to the IO terminal;
a second n-type doping region disposed on the silicon remaining layer, wherein the second n-type doping region forms a first cathode of the second diode and is configured to connect to the first voltage terminal; and
a second channel region disposed on the silicon remaining layer and between the second p-type doping region and the second n-type doping region.

14. The ESD protection circuit of claim 13,
wherein the first channel region comprises:
a first stack of silicon nanosheets disposed on the silicon remaining layer and between the first p-type doping region and the first n-type doping region; and
a first metal gate wrapping around each of the silicon nanosheets of the first stack of silicon nanosheets;
wherein the second channel region comprises:
a second stack of silicon nanosheets disposed on the silicon remaining layer and between the second p-type doping region and the second n-type doping region; and
a second metal gate wrapping around each of the silicon nanosheets of the second stack of silicon nanosheets.

15. The ESD protection circuit of claim 11, wherein the first diode further comprises:
a second p-type doping region disposed on the silicon remaining layer, wherein the second p-type doping region forms a second anode of the first diode and is configured to connect to the first anode;
a second n-type doping region disposed on the silicon remaining layer, wherein the second n-type doping region forms a second cathode of the first diode and is configured to connect to the first voltage terminal;
a second channel region disposed on the silicon remaining layer and between the first n-type doping region and the second n-type doping region, wherein the first channel region is disposed on the silicon remaining layer and between the first p-type doping region and the second p-type doping region; and
a third channel region disposed on the silicon remaining layer and between the second p-type doping region and the first n-type doping region.

16. The ESD protection circuit of claim 15,
wherein the first channel region comprises:
a first stack of silicon nanosheets disposed on the silicon remaining layer and a first metal gate wrapping around each of the silicon nanosheets of the first stack of silicon nanosheets;
wherein the second channel region comprises:
a second stack of silicon nanosheets disposed on the silicon remaining layer and a second metal gate wrapping around each of the silicon nanosheets of the second stack of silicon nanosheets; and
wherein the third channel region comprises:
a third stack of silicon nanosheets disposed on the silicon remaining layer and a third metal gate wrapping around each of the silicon nanosheets of the second stack of silicon nanosheets.

17. A method of forming a diode structure, comprising:
providing a substrate;
forming a first p-type doping region on the substrate;
forming a first n-type doping region on the substrate;
forming a first channel region on the substrate and between the first p-type doping region and the first n-type doping region; and
thinning a portion of the substrate to leave a silicon remaining layer below the first p-type doping region, the first n-type doping region and the first channel region.

18. The method of claim 17, wherein thinning the portion of the substrate includes forming the silicon remaining layer to have a thickness of 10 nm-100 nm.

19. The method of claim 17, further comprising:
forming a plurality of the first p-type doping regions on the substrate;
forming a plurality of the first n-type doping region on the substrate; and
forming a plurality of second channel regions on the substrate and between adjacent ones of the first p-type doping regions and/or adjacent ones of the first n-type doping regions.

20. The method of claim 17, wherein forming the first channel region includes:
forming a first stack of silicon nanosheets on the substrate and between the first p-type doping region and the first n-type doping region; and
forming a first metal gate wrapping around each of the silicon nanosheets of the first stack of silicon nanosheets.
